(19) United States
(12) Patent Application Publication
(10) Pub. No.: US 2020/0244089 A1
(43) Pub. Date: Jul. 30, 2020

(54) SECONDARY BATTERY STATE DETECTING SYSTEM, SECONDARY BATTERY STATE DETECTING DEVICE, AND SECONDARY BATTERY STATE DETECTING METHOD

(71) Applicant: HONDA MOTOR CO., LTD., Tokyo (JP)

(72) Inventor: Yoshikazu Nishida, Wako-shi (JP)

(21) Appl. No.: 16/739,150

(22) Filed: Jan. 10, 2020

(30) Foreign Application Priority Data
Jan. 25, 2019 (JP) 2019-011529

(51) Int. Cl. H02J 7/00; G01R 31/367; B60L 58/12; G06N 20/00; G06N 5/04

(52) U.S. Cl. CPC H02J 7/0048; H02J 7/00712; H02J 7/007194; G06N 5/04; B60L 58/12; G06N 20/00; G01R 31/367

(57) ABSTRACT

A secondary battery state detecting system includes: a model generating unit that generates a plurality of secondary battery models acquired by modeling characteristics of a plurality of secondary batteries mounted in a plurality of vehicles; a server unit that collects the plurality of secondary battery models generated by the model generating unit and provides the collected secondary battery models as secondary use secondary battery control information used for charging/discharging control of a secondary battery that is secondarily used; and a secondary battery state detecting device that executes charging/discharging control of the secondary battery that is secondarily used by using the secondary use secondary battery control information provided from the server unit.

### CROSS-REFERENCE TO RELATED APPLICATION

Priority is claimed on Japanese Patent Application No. 2019-011529, filed Jan. 25, 2019, the content of which is incorporated herein by reference.

### BACKGROUND OF THE INVENTION

### Field of the Invention

The present invention relates to a secondary battery state detecting system, a secondary battery state detecting device, and a secondary battery state detecting method.

### Description of Related Art

In Japanese Patent No. 6207127 (hereinafter, Patent Document 1), a measurement system including a battery pack having a battery built therein and at least one type of connection device to which the battery pack is connected is described. In the technology described in Patent Document 1, the charging capacity of a battery is calculated by detecting a discharge current from the battery in a first measurement range and detecting a charging current for the battery in a second measurement range smaller than the first measurement range.

In the technology described in Patent Document 1, in order to calculate the capacity of a battery, information relating to the battery at a time in the past at which the battery was used by another device is not used. In addition, in the technology described in Patent Document 1, in order to calculate the capacity of a battery, information relating to other batteries different from the battery is not used either.

In Japanese Patent No. 4960022 (hereinafter, Patent Document 2), a battery pack including a secondary battery, a voltage detecting unit that detects a cell voltage of the secondary battery, a current detecting unit that detects a charging/discharging current of the secondary battery, a communication unit that communicates with at least one of a charger and a load device, and a charging control unit that requests a charging current from the charger through the communication unit and controls a charging current for the secondary battery in response to detection results acquired by the voltage detecting unit and the current detecting unit is described. In the technology described in Patent Document 2, the charging control unit receives the terminal voltage of a charging/discharging terminal of the battery pack from a charger or a load device through the communication unit and divides the difference between the terminal voltage and a cell voltage detected by the voltage detecting unit by the current value detected by the current detecting unit, thereby acquiring a path resistance of a charging/discharging path used for charging/discharging.

However, in the technology described in Patent Document 2, in order to control the charging current to a secondary battery, information relating to the secondary battery at a time in the past at which the secondary battery was used by another device is not used. In addition, in the technology described in Patent Document 2, in order to control the charging current to the secondary battery, information relating to other secondary batteries different from the secondary battery is not used either.

### SUMMARY OF THE INVENTION

An aspect relating to the present invention is made in view of such situations, and one object thereof is to provide a secondary battery state detecting system, a secondary battery state detecting device, and a secondary battery state detecting method capable of appropriately controlling a secondary battery that is secondarily used.

In order to achieve a relating object by solving the problems described, the present invention employs the following aspects.

(1) According to one aspect of the present invention, there is provided a secondary battery state detecting system including: a model generating unit that generates a plurality of secondary battery models acquired by modeling characteristics of a plurality of secondary batteries mounted in a plurality of vehicles; a server unit that collects the plurality of secondary battery models generated by the model generating unit and provides the collected secondary battery models as secondary use secondary battery control information used for charging/discharging control of a secondary battery that is secondarily used; and a secondary battery state detecting device that executes charging/discharging control of the secondary battery that is secondarily used by using the secondary use secondary battery control information provided from the server unit.

(2) In the aspect (1) described above, at least currents, voltages, and temperatures of the plurality of secondary batteries may be input to the plurality of secondary battery models as input information, the plurality of secondary battery models may output at least one of internal resistance, capacitance, and SOC-OCV curves of the plurality of secondary batteries as output information, and the secondary battery state detecting device may execute charging/discharging control of the secondary battery that is secondarily used by using the secondary use secondary battery control information including the output information.

(3) In the aspect (2) described above, the secondary battery state detecting device may include a presentation unit that presents presentation information, and at least one of a battery type, an SOC, and an output power of the secondary battery that is secondarily used may be included in the presentation information.

(4) In the aspect (3) described above, information indicating whether or not the plurality of secondary batteries have malfunctioned may be included in the presentation information, and the secondary battery state detecting device may determine whether or not the plurality of secondary batteries have malfunctioned on the basis of the output information.

(5) In any one of the aspects (1) to (4) described above, the secondary battery state detecting device may include a detection unit that detects a current, a voltage, and a temperature of the secondary battery that is secondarily used, and the secondary battery state detecting device may execute charging/discharging control of the secondary battery that is secondarily used on the basis of the current, the voltage, and the temperature of the secondary battery, which is secondarily used, detected by the detection unit by using the secondary use secondary battery control information.

(6) In the aspect (5) described above, in a case in which the secondary battery that is secondarily used corresponds to none of the plurality of secondary batteries mounted in the plurality of vehicles, the secondary battery state detecting device may select an appropriate secondary battery model that is appropriate for charging/discharging control of the secondary battery that is secondarily used among the plurality of secondary battery models on the basis of the current, the voltage, and the temperature of the secondary battery, which is secondarily used, detected by the detection unit and execute charging/discharging control of the secondary battery that is secondarily used on the basis of the current, the voltage, and the temperature of the secondary battery, which is secondarily used, detected by the detection unit by using the appropriate secondary battery model.

(7) According to one aspect of the present invention, there is provided a secondary battery state detecting device that executes charging/discharging control of a secondary battery that is secondarily used, in which a model generating unit generates a plurality of secondary battery models acquired by modeling characteristics of a plurality of secondary batteries mounted in a plurality of vehicles, a server unit collects the plurality of secondary battery models generated by the model generating unit and provides the collected secondary battery models as secondary use secondary battery control information used for charging/discharging control of the secondary battery that is secondarily used, and the secondary battery state detecting device executes charging/discharging control of the secondary battery that is secondarily used by using the secondary use secondary battery control information provided from the server unit.

(8) According to one aspect of the present invention, there is provided a secondary battery state detecting method executing charging/discharging control of a secondary battery that is secondarily used, the secondary battery state detecting method including: generating a plurality of secondary battery models acquired by modeling characteristics of a plurality of secondary batteries mounted in a plurality of vehicles by using a model generating unit; collecting the plurality of secondary battery models generated by the model generating unit and providing the collected secondary battery models as secondary use secondary battery control information used for charging/discharging control of a secondary battery that is secondarily used by using a server unit; and acquiring the secondary use secondary battery control information provided by the server unit and executing charging/discharging control of the secondary battery that is secondarily used by using the secondary use secondary battery control information by using the secondary battery state detecting device.

According to the aspect (1) described above, the secondary battery state detecting device executes charging/discharging control of a secondary battery that is secondarily used by using a plurality of secondary battery models acquired by modeling characteristics of a plurality of secondary batteries mounted in a plurality of vehicles as secondary use secondary battery control information, and accordingly, the secondary battery that is secondarily used can be appropriately controlled.

According to the aspect (2) described above, the secondary battery state detecting device executes charging/discharging control of the secondary battery that is secondarily used by using the secondary use secondary battery control information including the output information output by the plurality of secondary battery models, and accordingly, charging/discharging control of the secondary battery that is secondarily used can be appropriately executed with output information of the plurality of secondary battery models reflected thereon.

According to the aspect (3) described above, the secondary battery state detecting device presents presentation information in which at least one of a battery type, an SOC, and an output of the secondary battery that is secondarily used is included, and accordingly, a user using the secondary battery that is secondarily used can perceive at least one of the battery type, the SOC, and the output of the secondary battery that is secondarily used.

According to the aspect (4) described above, information indicating whether or not a plurality of secondary batteries mounted in a plurality of vehicles have malfunctioned is included in the presentation information presented by the secondary battery state detecting device, and accordingly, a user using the secondary battery that is secondarily used can perceive whether or not the secondary battery that is secondarily used has malfunctioned.

According to the aspect (5) described above, the secondary battery state detecting device executes charging/discharging control of a secondary battery that is secondarily used on the basis of the current, the voltage, and the temperature of the secondary battery that is secondarily used, and accordingly, charging/discharging control of the secondary battery that is secondarily used can be appropriately executed by reflecting the current, the voltage, and the temperature of the secondary battery that is secondarily used on the plurality of secondary battery models.

According to the aspect (6) described above, in a case in which the secondary battery that is secondarily used corresponds to none of the plurality of secondary batteries mounted in the plurality of vehicles, the secondary battery state detecting device selects an appropriate secondary battery model that is appropriate for charging/discharging control of the secondary battery that is secondarily used among the plurality of secondary battery models on the basis of the current, the voltage, and the temperature of the secondary battery, which is secondarily used, and executes charging/discharging control of the secondary battery that is secondarily used by using the appropriate secondary battery model, and accordingly, even in a case in which the secondary battery that is secondarily used corresponds to none of the plurality of secondary batteries mounted in the plurality of vehicles, the secondary battery state detecting device can appropriately execute charging/discharging control of the secondary battery that is secondarily used by using the plurality of secondary battery models.

According to the aspect (7) described above, the secondary battery state detecting device executes charging/discharging control of a secondary battery that is secondarily used by using a plurality of secondary battery models acquired by modeling characteristics of a plurality of secondary batteries mounted in a plurality of vehicles as secondary use secondary battery control information, and accordingly, the secondary battery that is secondarily used can be appropriately controlled.

According to the aspect (8) described above, the secondary battery state detecting device executes charging/discharging control of a secondary battery that is secondarily used by using a plurality of secondary battery models acquired by modeling characteristics of a plurality of secondary batteries mounted in a plurality of vehicles as secondary use secondary battery control information, and accordingly, the secondary battery that is secondarily used can be appropriately controlled.

### BRIEF DESCRIPTION OF THE DRAWINGS

FIG. 1 is a diagram illustrating a first example of a secondary battery state detecting system according to a first embodiment;

FIG. 2 is a diagram illustrating one example of the configuration of a vehicle illustrated in FIG. 1;

FIG. 3 is a diagram illustrating one example of a secondary battery model generated by a model generating unit of a vehicle;

FIG. 4 is a sequence diagram illustrating one example of a process executed by a secondary battery state detecting system according to the first embodiment;

FIG. 5 is a diagram illustrating a first example of a secondary battery state detecting system according to a second embodiment; and

FIG. 6 is a sequence diagram illustrating one example of a process executed by a secondary battery state detecting system according to the second embodiment.

### DETAILED DESCRIPTION OF THE INVENTION

Hereinafter, a secondary battery state detecting system, a secondary battery state detecting device, and a secondary battery state detecting method according to embodiments of the present invention will be described with reference to the drawings.

### First Embodiment

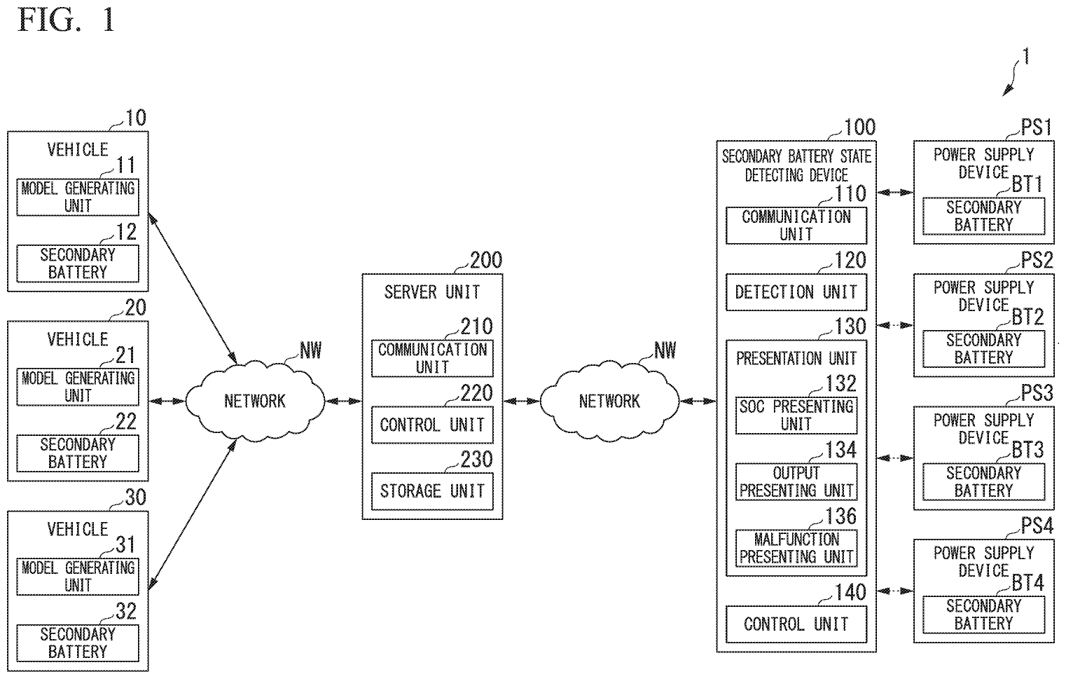

FIG. 1 is a diagram illustrating a first example of a secondary battery state detecting system according to a first embodiment;

In the example illustrated in FIG. 1, the secondary battery state detecting system 1, for example, includes three vehicles 10, 20, and 30, a server unit 200, a secondary battery state detecting device 100, and a power supply device PS1.

In another example, the secondary battery state detecting system 1 may include an arbitrary number of vehicles other than three.

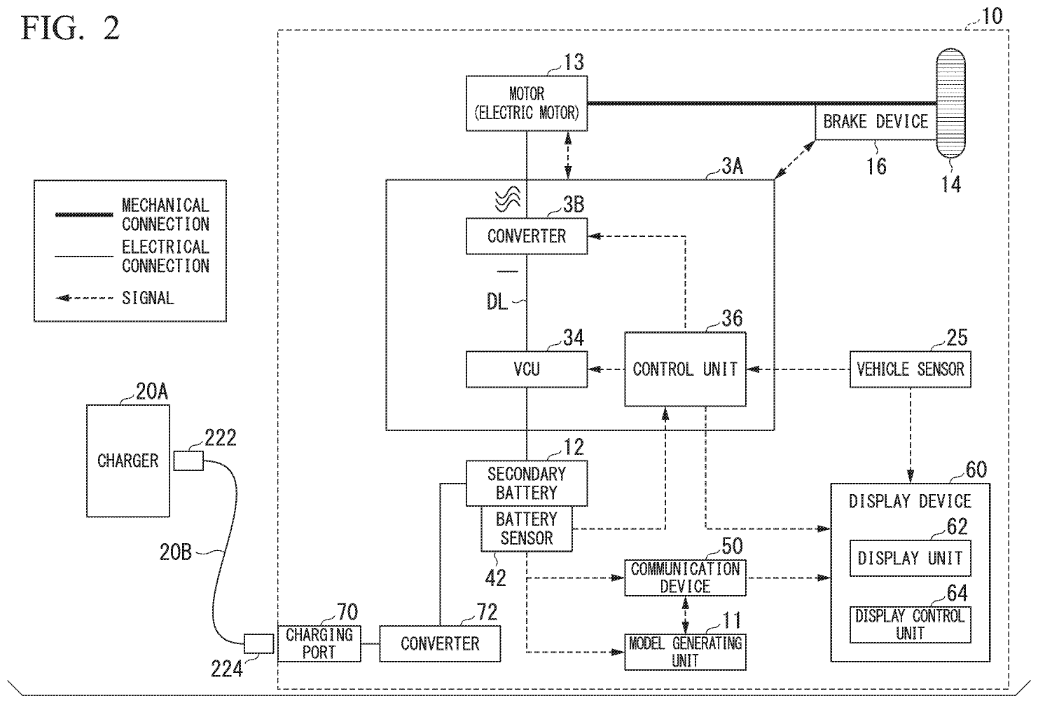

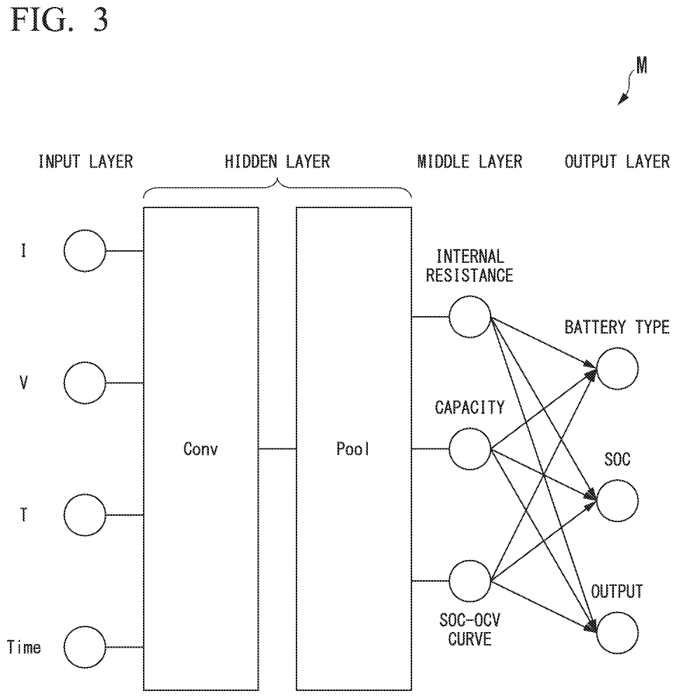

In the example illustrated in FIG. 1, the vehicle 10 includes a model generating unit 11 and a secondary battery 12. In other words, the secondary battery 12 is mounted in the vehicle 10. The model generating unit 11 generates a secondary battery model M (see FIG. 3) acquired by modeling characteristics of the secondary battery 12. In more detail, the model generating unit 11 generates a secondary battery model M on the basis of the current, the voltage, the temperature, and the like of the secondary battery 12 detected by a battery sensor 42 (see FIG. 2). The secondary battery model M is used for charging/discharging control of the secondary battery 12, estimation of the life of the secondary battery 12, and the like. The secondary battery model M generated by the model generating unit 11 is transmitted to the server unit 200 through a network NW using the communication device 50 (see FIG. 2). The network NW, for example, includes the Internet, a wide area network (WAN), a local area network (LAN), a provider device, a radio base station, and the like. The secondary battery 12, for example, is a battery that can repeat charging and discharging such as a nickel hydrogen battery, a lithium ion secondary battery, a sodium ion battery, or the like. At the time of discharging, the secondary battery 12 supplies electric power to a motor 13 (see FIG. 2) mounted in the vehicle 10.

The vehicle 20 includes a model generating unit 21 configured similar to the model generating unit 11 and a secondary battery 22. The model generating unit 21 generates a secondary battery model M (see FIG. 3) acquired by modeling characteristics of the secondary battery 22. The secondary battery model M is used for charging/discharging control of the secondary battery 22, estimation of the life of the secondary battery 22, and the like. The secondary battery model M generated by the model generating unit 21 is transmitted to the server unit 200 through the network NW using a communication device (not illustrated in the drawing) of the vehicle 20. The secondary battery 22 is a battery that can repeat charging and discharging similar to the secondary battery 12 and supplies electric power to a motor (not illustrated in the drawing) mounted in the vehicle 20 at the time of discharging.

The vehicle 30 includes a model generating unit 31 configured similar to the model generating unit 11 and a secondary battery 32. The model generating unit 31 generates a secondary battery model M (see FIG. 3) acquired by modeling characteristics of the secondary battery 32. The secondary battery model M is used for charging/discharging control of the secondary battery 32, estimation of the life of the secondary battery 32, and the like. The secondary battery model M generated by the model generating unit 31 is transmitted to the server unit 200 through the network NW using a communication device (not illustrated in the drawing) of the vehicle 30. The secondary battery 32 is a battery that can repeat charging and discharging similar to the secondary battery 12 and supplies electric power to a motor (not illustrated in the drawing) mounted in the vehicle 30 at the time of discharging.

The server unit 200 includes a communication unit 210, a control unit 220, and a storage unit 230. Such constituent elements, for example, are realized by a hardware processor such as a central processing unit (CPU) executing a program (software). Some or all of such constituent elements may be realized by hardware (a circuit unit; including circuitry) such as a large scale integration (LSI), an application specific integrated circuit (ASIC), a field-programmable gate array (FPGA), a graphics processing unit (GPU), and the like or may be realized by software and hardware in cooperation. The program may be stored in a storage device (a storage device including a non-transitory storage medium) such as a hard disk drive (HDD) or a flash memory in advance or may be stored in a loadable/removable storage medium (a non-transitory storage medium) such as a DVD or a CD-ROM and installed by mounting the storage medium in a drive device.

The communication unit 210 communicates with the vehicles 10, 20, and 30 and the secondary battery state detecting device 100. In more detail, the communication unit 210 receives the secondary battery model M transmitted from the vehicle 10, the secondary battery model M transmitted from the vehicle 20, and the secondary battery model M transmitted from the vehicle 30.

The control unit 220 collects secondary battery models M received by the communication unit 210. In other words, the control unit 220 collects the secondary model M generated by the model generating unit 11 of the vehicle 10, the secondary battery model M generated by the model generating unit 21 of the vehicle 20, and the secondary battery model M generated by the model generating unit 31 of the vehicle 30.

The storage unit 230 stores the secondary battery models M collected by the control unit 220. In other words, the storage unit 230 functions as a market battery database that stores a plurality of secondary battery models M acquired by modeling the characteristics of a plurality of secondary batteries 12, 22, and 32 mounted in a plurality of vehicles 10, 20, and 30 circulating in the market.

The server unit 200 provides a plurality of secondary battery models M stored in the storage unit 230 for the secondary battery state detecting device 100 as secondary use secondary battery control information used for charging/discharging control of a secondary battery BT1 that is secondarily used. In more detail, the communication unit 210 of the server unit 200 transmits a plurality of secondary battery models M as secondary use secondary battery control information to the secondary battery state detecting device 100 through the network NW.

The secondary battery state detecting device 100 includes a communication unit 110, a detection unit 120, a presentation unit 130, and a control unit 140. Such constituent elements, for example, are realized by a hardware processor such as a CPU executing a program (software). Some or all of such constituent elements may be realized by hardware such as an LSI, an ASIC, an FPGA, a GPU, or the like or may be realized by software and hardware in cooperation. The program may be stored in a storage device such as an HDD or a flash memory in advance or may be stored in a loadable/removable storage medium such as a DVD or a CD-ROM and installed by mounting the storage medium in a drive device.

The communication unit 110 communicates with the server unit 200 and the power supply device PS1. In more detail, the communication unit 110 receives a plurality of secondary battery models M as secondary use secondary battery control information transmitted from the server unit 200. In addition, the communication unit 110 receives information such as the current, the voltage, the temperature, and the like of a secondary battery BT1 mounted in the power supply device PS1 from the power supply device PS1. The current, the voltage, the temperature, and the like of the secondary battery BT1, for example, are detected by battery sensors (not illustrated in the drawing) mounted in the power supply device PS1. In other words, the secondary battery state detecting device 100 has a communication function of acquiring secondary use secondary battery control information (information required for charging/discharging control of the secondary battery BT1) provided by the server unit 200.

The detection unit 120 detects the current, the voltage, and the temperature of the secondary battery BT1 by acquiring the current, the voltage, and the temperature of the secondary battery BT1 received from the power supply device PS1 of the communication unit 110. In other words, the secondary battery state detecting device 100 has a sensing function of detecting the current, the voltage, and the temperature of the secondary battery BT1 mounted in the power supply device PS1.

The presentation unit 130 presents presentation information relating to the secondary battery BT1 mounted in the power supply device PS1, for example, to a user using the power supply device PS1, for example, using a display, a speech output, or the like. The presentation unit 130 includes an SOC presenting unit 132, an output presenting unit 134, and a malfunction presenting unit 136. The SOC presenting unit 132 presents a state of charge (SOC) [%] of the secondary battery BT1. The output presenting unit 134 presents an output [W] of the secondary battery BT1. The malfunction presenting unit 136 presents information representing whether or not the secondary battery BT1 has malfunctioned. In other words, the secondary battery state detecting device 100 has a function of malfunction monitoring of the secondary battery BT1.

The control unit 140 executes charging/discharging control of the secondary battery BT1 mounted in the power supply device PS1. In more detail, the control unit 140 executes charging/discharging control of the secondary battery BT1 by using a plurality of secondary battery models M (the secondary use secondary battery control information) provided from the server unit 200.

The power supply device PS1, for example, is a commercial power supply. The power supply device PS1 includes a secondary battery BT1 for which charging/discharging control is performed by the secondary battery state detecting device 100.

In a first example of the secondary battery state detecting system 1 according to the first embodiment illustrated in FIG. 1, for example, the secondary battery 12 mounted in the vehicle 10 is secondarily used as the secondary battery BT1.

When a secondary battery 12 is mounted in the vehicle 10, the model generating unit 11 of the vehicle 10 generates a secondary battery model M acquired by modeling the characteristics of the secondary battery 12. The secondary battery model M generated by the model generating unit 11 of the vehicle 10 is transmitted to the server unit 200 and is stored in the storage unit 230.

When the secondary battery state detecting device 100 executes charging/discharging control of the secondary battery 12 (the secondary battery BT1) that is secondarily used in the power supply device PS1, the secondary battery model M stored in the storage unit 230 of the server unit 200 is provided for the secondary battery state detecting device 100 as secondary use secondary battery control information. The control unit 140 of the secondary battery state detecting device 100 can appropriately execute charging/discharging control of the secondary battery 12 (the secondary battery BT1) that is secondarily used by using the secondary battery model M (the secondary use secondary battery control information). In more detail, the control unit 140 appropriately executes charging/discharging control of the secondary battery 12 (the secondary battery BT1) that is secondarily used on the basis of the current, the voltage, and the temperature of the secondary battery BT1 (in other words, the current, the voltage, and the temperature of the secondary battery BT1 used in the power supply device PS1) detected by the detection unit 120 using the secondary battery model M.

FIG. 2 is a diagram illustrating one example of the configuration of the vehicle 10 illustrated in FIG. 1.

In the example illustrated in FIG. 2, the vehicle 10, for example, includes a motor 13, drive wheels 14, a brake device 16, a vehicle sensor 25, a power control unit (PCU) 3A, a battery sensor 42 including a voltage sensor, a current sensor, a temperature sensor, and the like, a communication device 50, a display device 60, a charging port 70, and a converter 72 in addition to the model generating unit 11 and the secondary battery 12.

The motor 13, for example, is a three-phase AC electric motor. A rotor of the motor 13 is connected to the drive wheels 14. The motor 13 outputs power to the drive wheels 14 using electric power supplied from the secondary battery 12. In addition, the motor 13 generates power using kinetic energy of the vehicle 10 at the time of decelerating the vehicle 10.

The brake device 16, for example, includes a brake caliper, a cylinder delivering hydraulic pressure to the brake caliper, and an electric motor generating hydraulic pressure in the cylinder. The brake device 16 may include a mechanism that delivers a hydraulic pressure generated in accordance with an operation performed on a brake pedal to the cylinder through a master cylinder as a backup. The brake device 16 is not limited to the configuration described above and may be an electronic control-type hydraulic brake device that delivers a hydraulic pressure of the master cylinder to the cylinder.

The vehicle sensor 25 includes an acceleration opening degree sensor, a vehicle speed sensor, and a brake depression amount sensor. The acceleration opening degree sensor is mounted on an acceleration pedal that is one example of an operator accepting an acceleration instruction from a driver, detects the amount of operation of the acceleration pedal, and outputs the detected amount of operation to the control unit 36 as a degree of acceleration opening. The vehicle speed sensor, for example, includes vehicle wheel speed sensors attached to vehicle wheels and a speed calculator, derives a speed of the vehicle 10 (vehicle speed) by integrating vehicle wheel speeds detected by the vehicle wheel speed sensors, and outputs the derived speed to the control unit 36 and the display device 60. The brake depression amount sensor is mounted on the brake pedal, detects the amount of operation of the brake pedal, and outputs the detected amount of operation of the brake pedal to the control unit 36 as the amount of depression of the brake.

The PCU 3A, for example, includes a converter 3B, a voltage control unit (VCU) 34, and a control unit 36. In addition, such constituent elements being configured together as the PCU 3A is merely one example, and such constituent elements may be disposed in a distributed manner.

The converter 3B, for example, is an AC-DC converter. A DC-side terminal of the converter 3B is connected to a DC link DL. The secondary battery 12 is connected to the DC link DL through the VCU 34. The converter 3B converts an AC generated by the motor 13 into a DC and outputs the DC to the DC link DL.

The VCU 34, for example, is a DC-DC converter. The VCU 34 boosts electric power supplied from the secondary battery 12 and outputs the boosted electric power to the DC link DL.

The control unit 36, for example, includes a motor control unit, a brake control unit, and a battery VCU control unit. The motor control unit, the brake control unit, and the battery VCU control unit may be replaced with individual separate control devices, for example, control devices such as a motor ECU, a brake ECU, and a battery ECU.

The motor control unit controls the motor 13 on the basis of an output of the vehicle sensor 25. The brake control unit controls the brake device 16 on the basis of an output of the vehicle sensor 25. The battery VCU control unit calculates an SOC of the secondary battery 12 on the basis of an output of the battery sensor 42 attached to the secondary battery 12 and outputs the calculated SOC to the VCU 34 and the display device 60. The VCU 34 raises a voltage of the DC link DL in accordance with an instruction from the battery VCU control unit.

The secondary battery 12 stores electric power introduced from a charger 20A outside the vehicle 10 and performs discharging for running the vehicle 10. The battery sensor 42, for example, includes a current sensor, a voltage sensor, and a temperature sensor. The battery sensor 42, for example, detects the current, the voltage, and the temperature of the secondary battery 12. The battery sensor 42 outputs the current, the voltage, the temperature, and the like that have been detected to the control unit 36 and the communication device 50.

The communication device 50 includes a radio module used for a connection to a cellular network or a Wi-Fi network.

The communication device 50 acquires battery use status information such as the current, the voltage, the temperature, and the like output from the battery sensor 42 and transmits the acquired battery use status information to the server unit 200 through the network NW illustrated in FIG. 1. The communication device 50 adds battery type information and vehicle model information of a subject vehicle to the battery use status information to be transmitted. In addition, the communication device 50 receives information transmitted from the server unit 200 through the network NW. The communication device 50 outputs the received information to the display device 60.

As described above, the model generating unit 11 generates a secondary battery model M on the basis of the current, the voltage, the temperature, and the like of the secondary battery 12 detected by the battery sensor 42. In addition, the secondary battery model M generated by the model generating unit 11 is transmitted by the communication device 50 to the server unit 200 through the network NW.

The display device 60, for example, includes a display unit 62 and a display control unit 64. The display unit 62 displays information according to control of the display control unit 64. The display control unit 64 causes the display unit 62 to display information relating to the secondary battery 12 in accordance with information output from the control unit 36 and the communication device 50. In addition, the display control unit 64 causes the display unit 62 to display a vehicle speed and the like output from the vehicle sensor 25.

The charging port 70 is disposed toward the outside of the vehicle body of the vehicle 10. The charging port 70 is connected to the charger 20A through a charging cable 22B. The charging cable 22B includes a first plug 222 and a second plug 224. The first plug 222 is connected to the charger 20A, and the second plug 224 is connected to the charging port 70. Electricity supplied from the charger 20A is supplied to the charging port 70 through the charging cable 22B.

In addition, the charging cable 22B includes a signal cable mounted in a power cable. The signal cable relays communication between the vehicle 10 and the charger 20A. Accordingly, in each of the first plug 222 and the second plug 224, a power connector and a signal connector are disposed.

The converter 72 is disposed between the secondary battery 12 and the charging port 70. The converter 72 converts the current introduced from the charger 20A through the charging port 70, for example, an AC current into a DC current. The converter 72 outputs the converted DC current to the secondary battery 12.

FIG. 3 is a diagram illustrating one example of a secondary battery model M generated by the model generating unit 11, 21, or 31 of the vehicle 10.

In the example illustrated in FIG. 3, the secondary battery model M includes an input layer, a hidden layer, and an output layer. The hidden layer of the secondary battery model M, for example, includes one or more convolution neural network (CNN). The CNN includes Cony (convolution layer) and Pool (pooling layer). A current I, a voltage V, a temperature T, and a life elapse time Time of the secondary battery 12 (22 or 32) are input to the input layer of the secondary battery model M as input information. The life elapse time is a time that has elapsed after manufacturing of the secondary battery 12 (22 or 32). A middle layer of the secondary battery model M outputs internal resistance, capacitance, and an SOC-open circuit voltage (SOC-OCV) curve of the secondary battery 12 (22 or 32) as output information. The output layer of the secondary battery model M, for example, is fully coupled with the middle layer and outputs a battery type, an SOC, and an output of the secondary battery 12 (22 or 32) as presentation information. Parameters of the hidden layer are optimized by performing machine learning with inputs to the input layer set as learning data and data to be output from the middle layer or the output layer set as teacher data.

The model generating unit 11 (21 or 31) updates the secondary battery model M by inputting the current, the voltage, the temperature, and the life elapse time of the secondary battery 12 (22 or 32) to the input layer and performing machine learning.

In the example illustrated in FIG. 3, although the secondary battery model M is updated by performing machine learning, the secondary battery model M may not be updated in another example.

In the example illustrated in FIG. 3, the updated secondary battery model M is transmitted to the server unit 200 through the network NW and is stored in the storage unit 230. As described above, when the secondary battery state detecting device 100 executes charging/discharging control of the secondary battery 12 (the secondary battery BT1) that is secondarily used in the power supply device PS1, the secondary battery model M stored in the storage unit 230 of the server unit 200 is provided for the secondary battery state detecting device 100. The control unit 140 of the secondary battery state detecting device 100 executes charging/discharging control of the secondary battery 12 (the secondary battery BT1) that is secondarily used by using the secondary battery model M. In more details, at the time of executing charging/discharging control of the secondary battery 12 (the secondary battery BT1) that is secondarily used, the control unit 140 can use the output information and the presentation information including internal resistance, capacitance, an SOC-OCV curve, a battery type, an SOC, and an output that are output from the middle layer and the output layer of the secondary battery model M. In addition, the control unit 140 determines whether or not the secondary battery 12 (the secondary battery BT1) that is secondarily used has malfunctioned on the basis of the output information output from the middle layer of the secondary battery model M.

As described above, in the first example of the secondary battery state detecting system 1 according to the first embodiment illustrated in FIG. 1, the secondary battery state detecting system 1 includes the vehicles 10, 20, and 30, the server unit 200, the secondary battery state detecting device 100, and the power supply device PS1. On the other hand, in a second example of the secondary battery state detecting system 1 according to the first embodiment, the secondary battery state detecting system 1 includes vehicles 10, 20, and 30, a server unit 200, a secondary battery state detecting device 100, and a power supply device PS2 (see FIG. 1).

In other words, in the second example of the secondary battery state detecting system 1 according to the first embodiment, the secondary battery state detecting device 100 executes charging/discharging control of the secondary battery BT2 (see FIG. 1) mounted in the power supply device PS2. The power supply device PS2, for example, is a power supply for home use. As the secondary battery BT2, for example, the secondary battery 22 mounted in the vehicle 20 is secondarily used.

In addition, in the second example of the secondary battery state detecting system 1 according to the first embodiment, the server unit 200 provides a plurality of secondary battery models M stored in the storage unit 230 for the secondary battery state detecting device 100 as secondary use secondary battery control information used for charging/discharging control of the secondary battery BT2 that is secondarily used.

The communication unit 110 of the secondary battery state detecting device 100 communicates with the server unit 200 and the power supply device PS2. In more details, the communication unit 110 receives a plurality of secondary battery models M as secondary use secondary battery control information transmitted from the server unit 200. In addition, the communication unit 110 receives information such as the current, the voltage, the temperature, and the like of the secondary battery BT2 mounted in the power supply device PS2 from the power supply device PS2. For example, the current, the voltage, the temperature, and the like of the secondary battery BT2 are detected by a battery sensor (not illustrated in the drawing) mounted in the power supply device PS2. In other words, the secondary battery state detecting device 100 has a communication function of acquiring secondary use secondary battery control information (information required for charging/discharging control of the secondary battery BT2) provided by the server unit 200.

The communication unit 110 acquires the current, the voltage, and the temperature of the secondary battery BT2 received from the power supply device PS2, whereby the detection unit 120 of the secondary battery state detecting device 100 detects the current, the voltage, and the temperature of the secondary battery BT2. In other words, the secondary battery state detecting device 100 has a sensing function of detecting the current, the voltage, and the temperature of the secondary battery BT2 mounted in the power supply device PS2.

The presentation unit 130 of the secondary battery state detecting device 100 presents presentation information relating to the secondary battery BT2 mounted in the power supply device PS2, for example, to a user using the power supply device PS2. The SOC presenting unit 132 presents an SOC [%] of the secondary battery BT2. The output presenting unit 134 presents an output [W] of the secondary battery BT2. The malfunction presenting unit 136 presents information representing whether or not the secondary battery BT2 has malfunctioned. In other words, the secondary battery state detecting device 100 also has a malfunction monitoring function for the secondary battery BT2.

The control unit 140 of the secondary battery state detecting device 100 executes charging/discharging control of the secondary battery BT2 mounted in the power supply device PS2. In more details, the control unit 140 executes charging/discharging control of the secondary battery BT2 by using a secondary battery model M (secondary use secondary battery control information) provided from the server unit 200.

In more details, at the time of executing charging/discharging control of the secondary battery 22 (the secondary battery BT2) that is secondarily used, the control unit 140 can use the output information and the presentation information including internal resistance, capacitance, an SOC-OCV curve, a battery type, an SOC, and an output that are output from the middle layer and the output layer of the secondary battery model M. In addition, the control unit 140 determines whether or not the secondary battery 22 (the secondary battery BT2) that is secondarily used has malfunctioned on the basis of the output information output from the middle layer of the secondary battery model M.

In the second example of the secondary battery state detecting system 1 according to the first embodiment, when a secondary battery 22 is mounted in the vehicle 20, the model generating unit 21 of the vehicle 20 generates a secondary battery model M acquired by modeling characteristics of the secondary battery 22. The secondary battery model M generated by the model generating unit 21 of the vehicle 20 is transmitted to the server unit 200 and is stored in the storage unit 230.

When the secondary battery state detecting device 100 executes charging/discharging control of the secondary battery 22 (the secondary battery BT2) that is secondarily used in the power supply device PS2, the secondary battery model M stored in the storage unit 230 of the server unit 200 is provided for the secondary battery state detecting device 100 as secondary use secondary battery control information. The control unit 140 of the secondary battery state detecting device 100 can appropriately execute charging/discharging control of the secondary battery 22 (the secondary battery BT2) that is secondarily used by using the secondary battery model M (the secondary use secondary battery control information). In more details, the control unit 140 appropriately executes charging/discharging control of the secondary battery 22 (the secondary battery BT2) that is secondarily used on the basis of the current, the voltage, and the temperature of the secondary battery BT2 (in other words, the current, the voltage, and the temperature of the secondary battery BT2 used in the power supply device PS2) detected by the detection unit 120 using the secondary battery model M.

In a third example of the secondary battery state detecting system 1 according to the first embodiment, the secondary battery state detecting system 1 includes vehicles 10, 20, and 30, a server unit 200, a secondary battery state detecting device 100, and a power supply device PS3 (see FIG. 1).

In other words, in the third example of the secondary battery state detecting system 1 according to the first embodiment, the secondary battery state detecting device 100 executes charging/discharging control of the secondary battery BT3 (see FIG. 1) mounted in the power supply device PS3. The power supply device PS3, for example, is a portable power supply. As the secondary battery BT3, for example, the secondary battery 32 mounted in the vehicle 30 is secondarily used.

In addition, in the third example of the secondary battery state detecting system 1 according to the first embodiment, the server unit 200 provides a plurality of secondary battery models M stored in the storage unit 230 for the secondary battery state detecting device 100 as secondary use secondary battery control information used for charging/discharging control of the secondary battery BT3 that is secondarily used.

The communication unit 110 of the secondary battery state detecting device 100 communicates with the server unit 200 and the power supply device PS3. In more details, the communication unit 110 receives a plurality of secondary battery models M as secondary use secondary battery control information transmitted from the server unit 200. In addition, the communication unit 110 receives information such as the current, the voltage, the temperature, and the like of the secondary battery BT3 mounted in the power supply device PS3 from the power supply device PS3. For example, the current, the voltage, the temperature, and the like of the secondary battery BT3 are detected by a battery sensor (not illustrated in the drawing) mounted in the power supply device PS3. In other words, the secondary battery state detecting device 100 has a communication function of acquiring secondary use secondary battery control information (information required for charging/discharging control of the secondary battery BT3) provided by the server unit 200.

The communication unit 110 acquires a current, a voltage, and a temperature of the secondary battery BT3 received from the power supply device PS3, whereby the detection unit 120 of the secondary battery state detecting device 100 detects the current, the voltage, and the temperature of the secondary battery BT3. In other words, the secondary battery state detecting device 100 has a sensing function of detecting the current, the voltage, and the temperature of the secondary battery BT3 mounted in the power supply device PS3.

The presentation unit 130 of the secondary battery state detecting device 100 presents presentation information relating to the secondary battery BT3 mounted in the power supply device PS3, for example, to a user using the power supply device PS3. The SOC presenting unit 132 presents an SOC [%] of the secondary battery BT3. The output presenting unit 134 presents an output [W] of the secondary battery BT3. The malfunction presenting unit 136 presents information representing whether or not the secondary battery BT3 has malfunctioned. In other words, the secondary battery state detecting device 100 also has a malfunction monitoring function for the secondary battery BT3.

The control unit 140 of the secondary battery state detecting device 100 executes charging/discharging control of the secondary battery BT3 mounted in the power supply device PS3. In more details, the control unit 140 executes charging/discharging control of the secondary battery BT3 by using a secondary battery model M (secondary use secondary battery control information) provided from the server unit 200.

In more details, at the time of executing charging/discharging control of the secondary battery 32 (the secondary battery BT3) that is secondarily used, the control unit 140 can use the output information and the presentation information including internal resistance, capacitance, an SOC-OCV curve, a battery type, an SOC, and an output that are output from the middle layer and the output layer of the secondary battery model M. In addition, the control unit 140 determines whether or not the secondary battery 32 (the secondary battery BT3) that is secondarily used has malfunctioned on the basis of the output information output from the middle layer of the secondary battery model M.

In the third example of the secondary battery state detecting system 1 according to the first embodiment, when a secondary battery 32 is mounted in the vehicle 30, the model generating unit 31 of the vehicle 30 generates a secondary battery model M acquired by modeling characteristics of the secondary battery 32. The secondary battery model M generated by the model generating unit 31 of the vehicle 30 is transmitted to the server unit 200 and is stored in the storage unit 230.

When the secondary battery state detecting device 100 executes charging/discharging control of the secondary battery 32 (the secondary battery BT3) that is secondarily used in the power supply device PS3, the secondary battery model M stored in the storage unit 230 of the server unit 200 is provided for the secondary battery state detecting device 100 as secondary use secondary battery control information. The control unit 140 of the secondary battery state detecting device 100 can appropriately execute charging/discharging control of the secondary battery 32 (the secondary battery BT3) that is secondarily used by using the secondary battery model M (the secondary use secondary battery control information). In more details, the control unit 140 appropriately executes charging/discharging control of the secondary battery 32 (the secondary battery BT3) that is secondarily used on the basis of the current, the voltage, and the temperature of the secondary battery BT3 (in other words, the current, the voltage, and the temperature of the secondary battery BT3 used in the power supply device PS3) detected by the detection unit 120 using the secondary battery model M.

In a fourth example of the secondary battery state detecting system 1 according to the first embodiment, the secondary battery state detecting system 1 includes vehicles 10, 20, and 30, a server unit 200, a secondary battery state detecting device 100, and a power supply device PS4 (see FIG. 1).

In other words, in the fourth example of the secondary battery state detecting system 1 according to the first embodiment, the secondary battery state detecting device 100 executes charging/discharging control of the secondary battery BT4 (see FIG. 1) mounted in the power supply device PS4. The power supply device PS4 is a power supply for a vehicle mounted in a vehicle (not illustrated in the drawing) other than the vehicles 10, 20, and 30. As the secondary battery BT4, the secondary battery mounted in a vehicle (not illustrated in the drawing) other than the vehicles 10, 20, and 30 is secondarily used. In other words, the secondary battery BT4 that is secondarily used does not correspond to any one of a plurality of secondary batteries 12, 22, and 32 respectively mounted in a plurality of vehicles 10, 20 and 30.

In addition, in the fourth example of the secondary battery state detecting system 1 according to the first embodiment, the server unit 200 provides a plurality of secondary battery models M stored in the storage unit 230 for the secondary battery state detecting device 100 as secondary use secondary battery control information used for charging/discharging control of the secondary battery BT4 that is secondarily used.

The communication unit 110 of the secondary battery state detecting device 100 communicates with the server unit 200 and the power supply device PS4. In more details, the communication unit 110 receives a plurality of secondary battery models M as secondary use secondary battery control information transmitted from the server unit 200. In addition, the communication unit 110 receives information such as the current, the voltage, the temperature, and the like of the secondary battery BT4 mounted in the power supply device PS4 from the power supply device PS4. For example, the current, the voltage, the temperature, and the like of the secondary battery BT4 are detected by a battery sensor (not illustrated in the drawing) mounted in the power supply device PS4. In other words, the secondary battery state detecting device 100 has a communication function of acquiring secondary use secondary battery control information (information required for charging/discharging control of the secondary battery BT4) provided by the server unit 200.

The communication unit 110 acquires a current, a voltage, and a temperature of the secondary battery BT4 received from the power supply device PS4, whereby the detection unit 120 of the secondary battery state detecting device 100 detects the current, the voltage, and the temperature of the secondary battery BT4. In other words, the secondary battery state detecting device 100 has a sensing function of detecting the current, the voltage, and the temperature of the secondary battery BT4 mounted in the power supply device PS4.

The presentation unit 130 of the secondary battery state detecting device 100 presents presentation information relating to the secondary battery BT4 mounted in the power supply device PS4, for example, to a user using the power supply device PS4. The SOC presenting unit 132 presents an SOC [%] of the secondary battery BT4. The output presenting unit 134 presents an output [W] of the secondary battery BT4. The malfunction presenting unit 136 presents information representing whether or not the secondary battery BT4 has malfunctioned. In other words, the secondary battery state detecting device 100 also has a malfunction monitoring function for the secondary battery BT4.

As described above, in the fourth example of the secondary battery state detecting system 1 according to the first embodiment, the secondary battery BT4 that is secondarily used does not correspond to any one of the plurality of secondary batteries 12, 22, and 32 respectively mounted in the plurality of vehicles 10, 20, and 30. Thus, the control unit 140 of the secondary battery state detecting device 100 selects an appropriate secondary battery model (for example, a secondary battery model acquired by modeling characteristics of the secondary battery 22) that is appropriate for charging/discharging control of the secondary battery BT4 that is secondarily used among the plurality of secondary battery models M received by the communication unit 110 on the basis of the current, a voltage, and a temperature of the secondary battery BT4, which is secondarily used, detected by the detection unit 120.

The control unit 140 executes charging/discharging control of the secondary battery BT4 by using the selected appropriate secondary battery model (for example, the secondary battery model M acquired by modeling the characteristics of the secondary battery 22). In more details, the control unit 140 executes charging/discharging control of the secondary battery BT4 that is secondarily used on the basis of the current, the voltage, and the temperature of the secondary battery BT4, which is secondarily used, detected by the detection unit 120 by using the selected appropriate secondary battery model (for example, the secondary battery model M acquired by modeling the characteristics of the secondary battery 22).

In addition, at the time of executing charging/discharging control of the secondary battery BT4 that is secondarily used, the control unit 140 can use the output information and the presentation information including internal resistance, capacitance, an SOC-OCV curve, a battery type, an SOC, and an output that are output from the middle layer and the output layer of the appropriate secondary battery model M (for example, a secondary battery model M that is acquired by modeling the characteristics of the secondary battery 22). In addition, the control unit 140 determines whether or not the secondary battery BT4 that is secondarily used has malfunctioned on the basis of the output information output from the middle layer of the appropriate secondary battery model M (for example, a secondary battery model M that is acquired by modeling the characteristics of the secondary battery 22).

In the fourth example of the secondary battery state detecting system 1 according to the first embodiment, when a secondary battery 22 is mounted in the vehicle 20, the model generating unit 21 of the vehicle 20 generates a secondary battery model M acquired by modeling characteristics of the secondary battery 22. The secondary battery model M generated by the model generating unit 21 of the vehicle 20 is transmitted to the server unit 200 and is stored in the storage unit 230.

When the secondary battery state detecting device 100 executes charging/discharging control of the secondary battery BT4 that is secondarily used in the power supply device PS4, the secondary battery model M (for example, a secondary battery model M that is acquired by modeling the characteristics of the secondary battery 22) stored in the storage unit 230 of the server unit 200 is provided for the secondary battery state detecting device 100 as an appropriate secondary battery model (secondary use secondary battery control information). The control unit 140 of the secondary battery state detecting device 100 can appropriately execute charging/discharging control of the secondary battery BT4 that is secondarily used by using the appropriate secondary battery model (for example, a secondary battery model M that is acquired by modeling the characteristics of the secondary battery 22). In more details, the control unit 140 appropriately executes charging/discharging control of the secondary battery BT4 that is secondarily used on the basis of the current, the voltage, and the temperature of the secondary battery BT4 (in other words, the current, the voltage, and the temperature of a secondary battery BT4 having characteristics and/or the characteristics close to uses and/or uses of the secondary battery 22) detected by the detection unit 120 using the appropriate secondary battery model (for example, a secondary battery model M that is acquired by modeling the characteristics of the secondary battery 22).

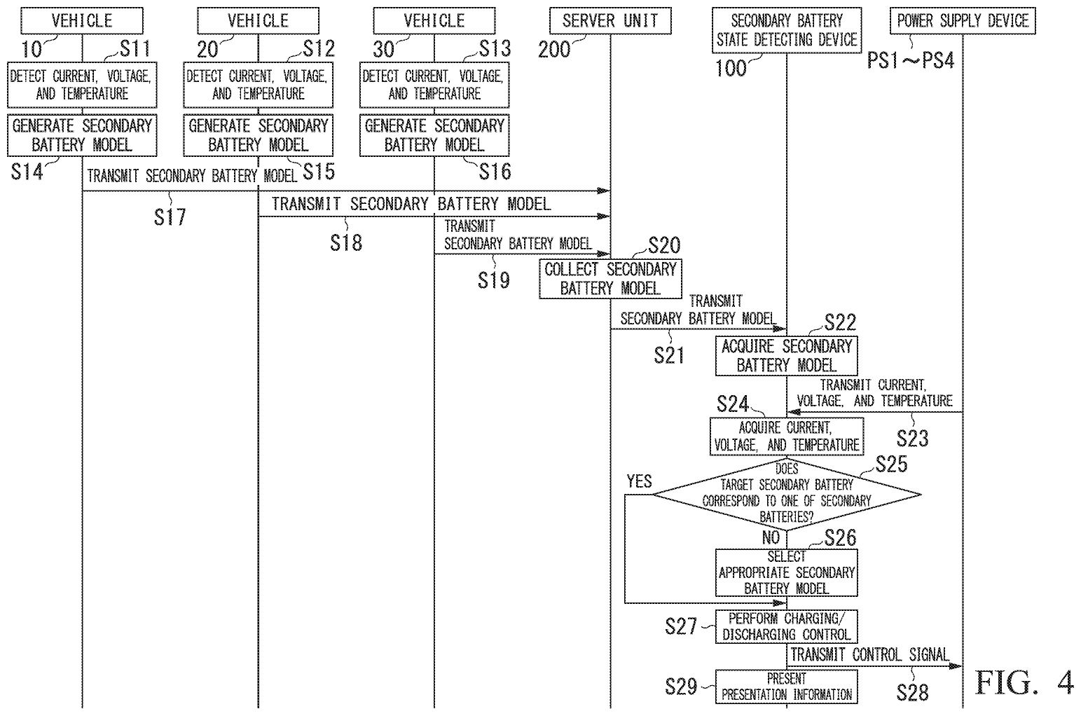

FIG. 4 is a sequence diagram illustrating one example of a process executed by the secondary battery state detecting system 1 according to the first embodiment.

In the example illustrated in FIG. 4, first, the battery sensor 42 of the vehicle 10 detects the current, the voltage, and the temperature of the secondary battery 12 (Step S11). In addition, the battery sensor of the vehicle 20 detects the current, the voltage, and the temperature of the secondary battery 22 (Step S12). Furthermore, the battery sensor of the vehicle 30 detects the current, the voltage, and the temperature of the secondary battery 32 (Step S13).

Next, the model generating unit 11 of the vehicle 10 generates a secondary battery model M acquired by modeling characteristics of the secondary battery 12 (Step S14). In addition, the model generating unit 21 of the vehicle 20 generates a secondary battery model M acquired by modeling characteristics of the secondary battery 22 (Step S15). Furthermore, the model generating unit 31 of the vehicle 30 generates a secondary battery model M acquired by modeling characteristics of the secondary battery 32 (Step S16).

Next, the communication device 50 of the vehicle 10 transmits the secondary battery model M to the server unit 200 (Step S17). In addition, the communication device of the vehicle 20 transmits the secondary battery model M to the server unit 200 (Step S18). Furthermore, the communication device of the vehicle 30 transmits the secondary battery model M to the server unit 200 (Step S19).

Next, the control unit 220 of the server unit 200 collects the secondary battery model M transmitted from the vehicle 10, the secondary battery model M transmitted from the vehicle 20, and the secondary battery model M transmitted from the vehicle 30 and stores them in the storage unit 230 (Step S20). Next, the communication unit 210 of the server unit 200 transmits the plurality of secondary battery models M as secondary use secondary battery control information to the secondary battery state detecting device 100 (Step S21), and the secondary battery state detecting device 100 acquires the plurality of secondary battery models M as the secondary use secondary battery control information (Step S22).

In addition, the power supply device (any one of the power supply devices PS1, PS2, PS3, and PS4) transmits information, i.e., the current, the voltage, and the temperature of the secondary battery (any one of the secondary batteries BT1, BT2, BT3, and BT4) to the secondary battery state detecting device 100 (Step S23). Next, the detection unit 120 of the secondary battery state detecting device 100 acquires the current, the voltage, and the temperature of the secondary battery (any one of the secondary batteries BT1, BT2, BT3, and BT4) that is a charging/discharging control target according to the secondary battery state detecting device 100 (Step S24).

Next, the control unit 140 of the secondary battery state detecting device 100 determines whether or not the secondary battery that is a charging/discharging control target according to the secondary battery state detecting device 100 corresponds to any one of the secondary batteries 12, 22, and 32 respectively mounted in the vehicles 10, 20, and 30 (in other words, whether or not one of the secondary batteries 12, 22, and 32 respectively mounted in the vehicles 10, 20, and 30 is secondarily used) (Step S25).

In a case in which the secondary battery that is a charging/discharging control target according to the secondary battery state detecting device 100 corresponds to any one of the secondary batteries 12, 22, and 32 respectively mounted in the vehicles 10, 20, and 30 (Step S25: Yes), the process proceeds to Step S27. On the other hand, in the case in which the secondary battery that is a charging/discharging control target according to the secondary battery state detecting device 100 does not correspond to any one of the secondary batteries 12, 22, and 32 respectively mounted in the vehicles 10, 20, and 30 (Step S25: No), the control unit 140 of the secondary battery state detecting device 100 selects an appropriate secondary battery model (for example, a secondary battery model M acquired by modeling characteristics of the secondary battery 22) that is appropriate for charging/discharging control of the secondary battery that is a charging/discharging control target among the plurality of secondary battery models M acquired in Step S22 on the basis of the current, the voltage, and the temperature of the secondary battery, which is a charging/discharging control target, acquired in Step S24 (Step S26).

Next, the control unit 140 of the secondary battery state detecting device 100 executes charging/discharging control of the secondary battery that is a charging/discharging control target by using a secondary battery model (any one of the plurality of secondary battery models M) acquired by modeling characteristics of the secondary battery (any one of the secondary batteries 12, 22, and 32) corresponding to the secondary battery that is a charging/discharging control target or using an appropriate secondary battery model (for example, a secondary battery model M acquired by modeling the characteristics of the secondary battery 22) selected in Step S26. In more details, the control unit 140 of the secondary battery state detecting device 100 generates a charging/discharging control signal used for charging/discharging control of the secondary battery that is a charging/discharging control target (Step S27).

Next, the communication unit 110 of the secondary battery state detecting device 100 transmits the charging/discharging control signal generated in Step S27 to the power supply device in which the secondary battery that is a charging/discharging control target is mounted (any one of the power supply devices PS1, PS2, PS3, and PS4) (Strep S28). In addition, the presentation unit 130 of the secondary battery state detecting device 100 presents presentation information relating to the secondary battery that is a charging/discharging control target (Step S29).

As described above, according to the secondary battery state detecting system 1 of the first embodiment, the states of the secondary batteries BT1, BT2, BT3, and BT4 that are secondarily used respectively in the power supply devices PS1, PS2, PS3, and PS4 are appropriately perceived, and charging/discharging control of the secondary batteries BT1, BT2, BT3, and BT4 can be appropriately performed. In more details, a controller that is dedicatedly used in each of the secondary batteries BT1, BT2, BT3, and BT4 that are secondarily used does not need to be designed, and the secondary battery state detecting device 100 can appropriately perform charging/discharging control of any one of the secondary batteries BT1, BT2, BT3, and BT4 as well.

In the first to fourth examples of the secondary battery state detecting system 1 according to the first embodiment, although the secondary battery state detecting device 100 performs state detection and malfunction monitoring of the secondary batteries BT1, BT2, BT3, and BT4 that are secondarily used, in another example of the secondary battery state detecting system 1 according to the first embodiment, the secondary battery state detecting device 100 may perform state detection and malfunction monitoring of all the secondary batteries (including secondary batteries having no history of being secondarily used) by using the secondary use secondary battery control information provided from the server unit 200. In other words, the secondary battery state detecting device 100 of the secondary battery state detecting system 1 according to the first embodiment is a general-purpose controller that appropriately performs state detection and malfunction monitoring of all the secondary batteries having characteristics and/or the characteristics close to uses and/or uses of a secondary battery that is a secondary battery model source provided from the server unit 200.

### Second Embodiment

Hereinafter, a secondary battery state detecting system, a secondary battery state detecting device, and a secondary battery state detecting method according to a second embodiment of the present invention will be described. The secondary battery state detecting system 1 according to the second embodiment is configured similar to the secondary battery state detecting system 1 according to the first embodiment described above except for points to be described later. Thus, according to the secondary battery state detecting system 1 of the second embodiment, except for the points to be described later, effects similar to those of the secondary battery state detecting system 1 according to the first embodiment described above can be acquired.

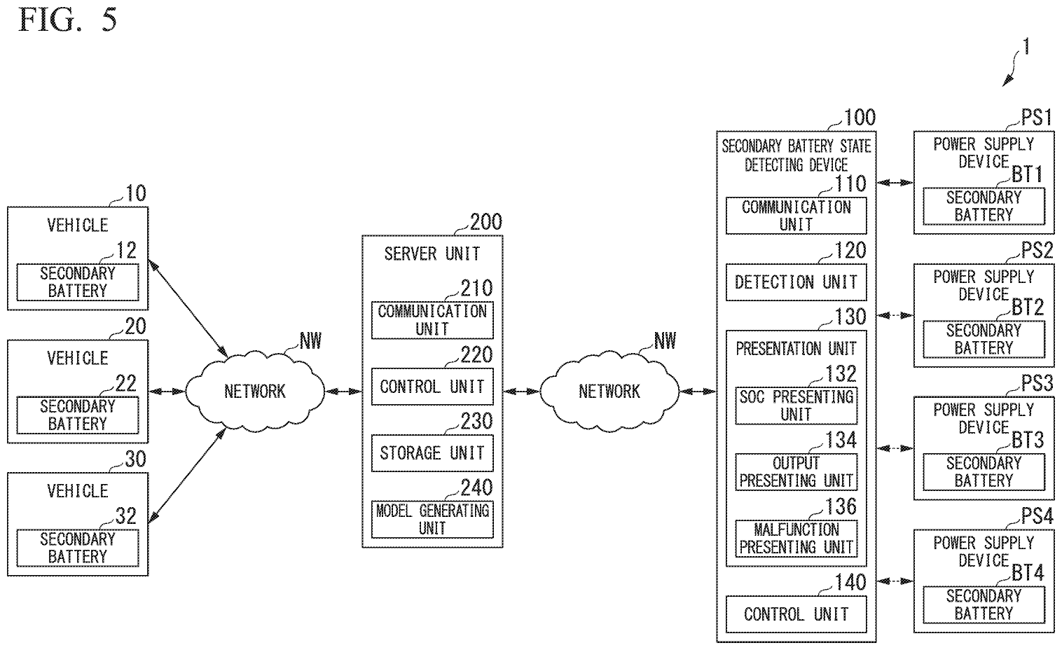

FIG. 5 is a diagram illustrating a first example of the secondary battery state detecting system 1 according to the second embodiment.

In the example illustrated in FIG. 1, although the vehicle 10 includes the model generating unit 11, the vehicle 20 includes the model generating unit 21, and the vehicle 30 includes the model generating unit 31, in the example illustrated in FIG. 5, a vehicle 10 includes no model generating unit, a vehicle 20 includes no model generating unit, and a vehicle 30 includes no model generating unit. In the example illustrated in FIG. 1, although the server unit 200 includes no model generating unit, a server unit 200 includes a model generating unit 240 in the example illustrated in FIG. 5.

In the example illustrated in FIG. 5, a communication device 50 of a vehicle 10 transmits information such as the current, the voltage, the temperature, and the like of a secondary battery 12 detected by a battery sensor 42 of the vehicle 10 to the server unit 200.

The communication device of the vehicle 20 transmits information such as a current, a voltage, a temperature, and the like of the secondary battery 22 detected by the battery sensor of the vehicle 20 to the server unit 200. In addition, the communication device of the vehicle 30 transmits information such as the current, the voltage, the temperature, and the like of the secondary battery 32 detected by the battery sensor of the vehicle 30 to the server unit 200.

A communication unit 210 of the server unit 200 receives the information of the current, the voltage, the temperature, and the like of the secondary battery 12 transmitted from the vehicle 10, the information of the current, the voltage, the temperature, and the like of the secondary battery 22 transmitted from the vehicle 20, and the information of the current, the voltage, the temperature, and the like of the secondary battery 32 transmitted from the vehicle 30. A model generating unit 240 generates a secondary battery model M acquired by modeling characteristics of the secondary battery 12 on the basis of the current, the voltage, the temperature, and the like of the secondary battery 12. In addition, the model generating unit 240 generates a secondary battery model M acquired by modeling characteristics of the secondary battery 22 on the basis of the current, the voltage, the temperature, and the like of the secondary battery 22 and generates a secondary battery model M acquired by modeling characteristics of the secondary battery 32 on the basis of the current, the voltage, the temperature, and the like of the secondary battery 32.

A control unit 220 collects a plurality of the secondary battery models M generated by the model generating unit 240.

A storage unit 230 stores the plurality of secondary battery models M collected by the control unit 220.

The server unit 200 provides the plurality of secondary battery models stored in the storage unit 230 for the secondary battery state detecting device 100 as secondary use secondary battery control information used for charging/discharging control of the secondary battery BT1 that is secondarily used.

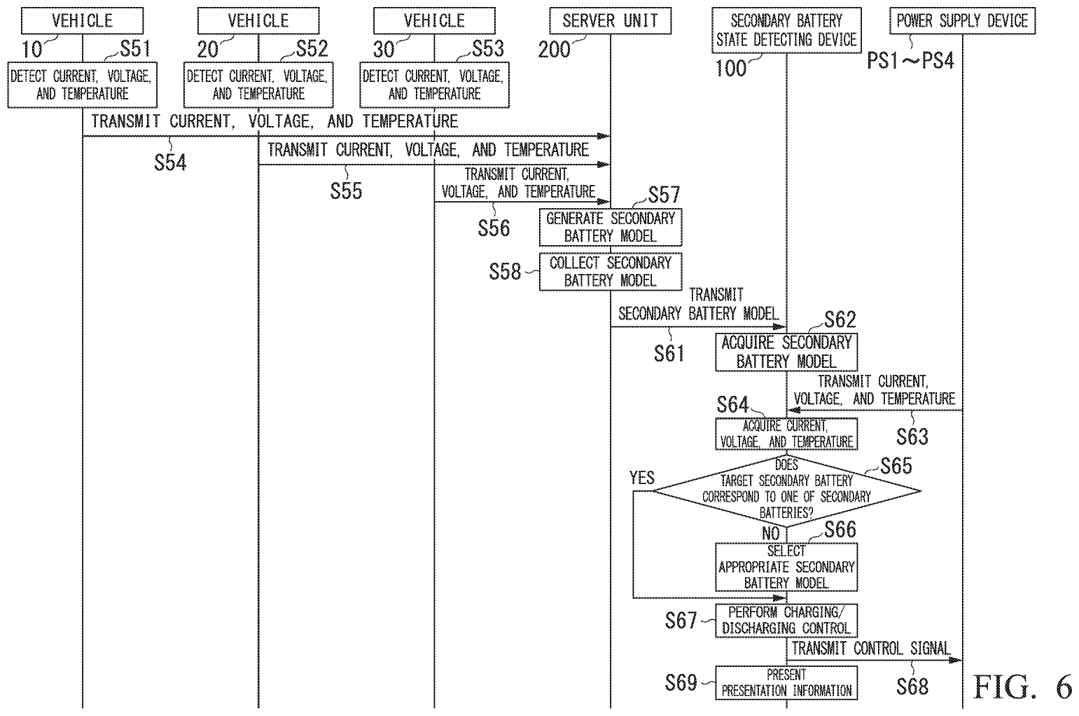

FIG. 6 is a sequence diagram illustrating one example of a process executed by the secondary battery state detecting system 1 according to the second embodiment.

In the example illustrated in FIG. 6, first, the battery sensor 42 of the vehicle 10 detects the current, the voltage, and the temperature of the secondary battery 12 (Step S51). In addition, the battery sensor of the vehicle 20 detects the current, the voltage, and the temperature of the secondary battery 22 (Step S52). Furthermore, the battery sensor of the vehicle 30 detects the current, the voltage, and the temperature of the secondary battery 32 (Step S53).

Next, the communication device 50 of the vehicle 10 transmits information of the current, the voltage, the temperature, and the like of the secondary battery 12 to the server unit 200 (Step S54). In addition, the communication device of the vehicle 20 transmits information of the current, the voltage, the temperature, and the like of the secondary battery 22 to the server unit 200 (Step S55). Furthermore, the communication device of the vehicle 30 transmits information of the current, the voltage, the temperature, and the like of the secondary battery 32 to the server unit 200 (Step S56).

Next, the model generating unit 240 of the server unit 200 generates a secondary battery model M acquired by modeling characteristics of the secondary battery 12 on the basis of the current, the voltage, the temperature, and the like of the secondary battery 12, generates a secondary battery model M acquired by modeling characteristics of the secondary battery 22 on the basis of the current, the voltage, the temperature, and the like of the secondary battery 22, and generates a secondary battery model M acquired by modeling characteristics of the secondary battery 32 on the basis of the current, the voltage, the temperature, and the like of the secondary battery 32 (Step S57). Next, the control unit 220 of server unit 200 collects a plurality of secondary battery models M, and the storage unit 230 stores them therein (Step S58). Next, the communication unit 210 of the server unit 200 transmits the plurality of secondary battery models M as secondary use secondary battery control information to the secondary battery state detecting device 100 (Step S61), and the secondary battery state detecting device 100 acquires the plurality of secondary battery models M as the secondary use secondary battery control information (Step S62).

In addition, a power supply device (any one of power supply devices PS1, PS2, PS3, and PS4) transmits information of the current, the voltage, and the temperature of a secondary battery (any one of the secondary batteries BT1, BT2, BT3, and BT4) to the secondary battery state detecting device 100 (Step S63). Next, the detection unit 120 of the secondary battery state detecting device 100 acquires the current, the voltage, and the temperature of a secondary battery (any one of the secondary batteries BT1, BT2, BT3, and BT4) that is a charging/discharging control target according to the secondary battery state detecting device 100 (Step S64).

Next, the control unit 140 of the secondary battery state detecting device 100 determines whether or not the secondary battery that is a charging/discharging control target according to the secondary battery state detecting device 100 corresponds to any one of the secondary batteries 12, 22, and 32 respectively mounted in the vehicles 10, 20, and 30 (in other words, whether or not any one of the secondary batteries 12, 22, and 32 respectively mounted in the vehicles 10, 20, and 30 is secondarily used) (Step S65).

In a case in which the secondary battery that is a charging/discharging control target according to the secondary battery state detecting device 100 corresponds to any one of the secondary batteries 12, 22, and 32 respectively mounted in the vehicles 10, 20, and 30 (Step S65: Yes), the process proceeds to Step S67. On the other hand, in a case in which the secondary battery that is a charging/discharging control target according to the secondary battery state detecting device 100 corresponds to none of the secondary batteries 12, 22, and 32 respectively mounted in the vehicles 10, 20, and 30 (Step S65: No), the control unit 140 of the secondary battery state detecting device 100 selects an appropriate secondary battery model (for example, a secondary battery model M acquired by modeling the characteristics of the secondary battery 22) that is appropriate for charging/discharging control of the secondary battery that is a charging/discharging control target among the plurality of secondary battery models M acquired in Step S62 on the basis of the current, the voltage, and the temperature of the secondary battery that is a charging/discharging control target acquired in Step S64 (Step S66).

Next, the control unit 140 of the secondary battery state detecting device 100 executes charging/discharging control of the secondary battery that is a charging/discharging control target by using a secondary battery model (any one of the plurality of secondary battery models M) acquired by modeling the characteristics of the secondary battery (any one of the secondary batteries 12, 22, and 32) corresponding to the secondary battery that is a charging/discharging control target or by using the appropriate secondary battery model (for example, the secondary battery model M acquired by modeling the characteristics of the secondary battery 22) selected in Step S66. In more details, the control unit 140 of the secondary battery state detecting device 100 generates a charging/discharging control signal used for charging/discharging control of the secondary battery that is a charging/discharging control target (Step S67).

Next, the communication unit 110 of the secondary battery state detecting device 100 transmits the charging/discharging control signal generated in Step S67 to a power supply device (any one of the power supply devices PS1, PS2, PS3, and PS4) in which the secondary battery that is the charging/discharging control target is mounted (Step S68). In addition, the presentation unit 130 of the secondary battery state detecting device 100 presents presentation information relating to the secondary battery that is the charging/discharging control target (Step S69).

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A secondary battery state detecting system comprising:
a model generating unit that generates a plurality of secondary battery models acquired by modeling characteristics of a plurality of secondary batteries mounted in a plurality of vehicles;
a server unit that collects the plurality of secondary battery models generated by the model generating unit and provides the collected secondary battery models as secondary use secondary battery control information used for charging/discharging control of a secondary battery that is secondarily used; and
a secondary battery state detecting device that executes charging/discharging control of the secondary battery that is secondarily used by using the secondary use secondary battery control information provided from the server unit.

2. The secondary battery state detecting system according to claim 1,
wherein at least currents, voltages, and temperatures of the plurality of secondary batteries are input to the plurality of secondary battery models as input information,
wherein the plurality of secondary battery models output at least one of internal resistance, capacitance, and SOC-OCV curves of the plurality of secondary batteries as output information, and
wherein the secondary battery state detecting device executes charging/discharging control of the secondary battery that is secondarily used by using the secondary use secondary battery control information including the output information.

3. The secondary battery state detecting system according to claim 2,
wherein the secondary battery state detecting device includes a presentation unit that presents presentation information, and
wherein at least one of a battery type, an SOC, and an output power of the secondary battery that is secondarily used is included in the presentation information.

4. The secondary battery state detecting system according to claim 3,
wherein information indicating whether or not the plurality of secondary batteries have malfunctioned is included in the presentation information, and
wherein the secondary battery state detecting device determines whether or not the plurality of secondary batteries have malfunctioned on the basis of the output information.

5. The secondary battery state detecting system according to claim 1,
wherein the secondary battery state detecting device includes a detection unit that detects a current, a voltage, and a temperature of the secondary battery that is secondarily used, and
wherein the secondary battery state detecting device executes charging/discharging control of the secondary battery that is secondarily used on the basis of the current, the voltage, and the temperature of the secondary battery, which is secondarily used, detected by the detection unit by using the secondary use secondary battery control information.

6. The secondary battery state detecting system according to claim 5, wherein, in a case in which the secondary battery that is secondarily used corresponds to none of the plurality of secondary batteries mounted in the plurality of vehicles, the secondary battery state detecting device selects an appropriate secondary battery model that is appropriate for charging/discharging control of the secondary battery that is secondarily used among the plurality of secondary battery models on the basis of the current, the voltage, and the temperature of the secondary battery, which is secondarily used, detected by the detection unit and executes charging/discharging control of the secondary battery that is secondarily used on the basis of the current, the voltage, and the temperature of the secondary battery, which is secondarily used, detected by the detection unit by using the appropriate secondary battery model.

7. A secondary battery state detecting device that executes charging/discharging control of a secondary battery that is secondarily used,
wherein a model generating unit generates a plurality of secondary battery models acquired by modeling characteristics of a plurality of secondary batteries mounted in a plurality of vehicles,
wherein a server unit collects the plurality of secondary battery models generated by the model generating unit and provides the collected secondary battery models as secondary use secondary battery control information used for charging/discharging control of the secondary battery that is secondarily used, and
wherein the secondary battery state detecting device executes charging/discharging control of the secondary battery that is secondarily used by using the secondary use secondary battery control information provided from the server unit.

8. A secondary battery state detecting method executing charging/discharging control of a secondary battery that is secondarily used, the secondary battery state detecting method comprising:
generating a plurality of secondary battery models acquired by modeling characteristics of a plurality of secondary batteries mounted in a plurality of vehicles by using a model generating unit;
collecting the plurality of secondary battery models generated by the model generating unit and providing the collected secondary battery models as secondary use secondary battery control information used for charging/discharging control of a secondary battery that is secondarily used by using a server unit; and
acquiring the secondary use secondary battery control information provided by the server unit and executing charging/discharging control of the secondary battery that is secondarily used by using the secondary use secondary battery control information by using the secondary battery state detecting device.
